(19) United States
(12) Patent Application Publication
(10) Pub. No.: US 2026/0333701 A1
(43) Pub. Date: Oct. 22, 2026

(54) SEMICONDUCTOR DEVICE INCLUDING GATE INSULATING LAYER

(71) Applicant: Samsung Electronics Co., Ltd., Suwon-si (KR)

(72) Inventors: Youngji Noh, Suwon-si (KR); Hanseung Ko, Suwon-si (KR); Jongho Woo, Suwon-si (KR); Kwangsoo Kim, Suwon-si (KR); Wanki Kim, Suwon-si (KR)

(21) Appl. No.: 19/410,735

(22) Filed: Dec. 5, 2025

(30) Foreign Application Priority Data
Apr. 22, 2025 (KR) 10-2025-0052573

(51) Int. Cl. H10B 51/20; H10B 51/10; H10B 51/30

(52) U.S. Cl. CPC H10B 51/20; H10B 51/10; H10B 51/30

(57) ABSTRACT

The present disclosure relates to a semiconductor device. In an example semiconductor device, a gate insulating layer is formed in a structure other than a channel structure, and thus, the gate insulating layer having a small thickness may be formed relatively easily, thereby improving electrical characteristics of the semiconductor device. In addition, when forming a plurality of plug structures in a stepped configuration in a connection region, a gate insulating layer extension may be used as an etch stop layer. Accordingly, the semiconductor device may reduce a process variation of a stair-free contact structure, even when the number of layers of word lines increases.

### CROSS-REFERENCE TO RELATED APPLICATION

This application claims priority under 35 U.S.C. §119 to Korean Patent Application No. 10-2025-0052573, filed on Apr. 22, 2025, in the Korean Intellectual Property Office, the disclosure of which is incorporated by reference herein in its entirety.

### BACKGROUND

In order to achieve excellent performance and economic efficiency, it is desired to increase the degree of integration of semiconductor devices. In particular, the degree of integration of memory devices is an important factor in determining the economic efficiency of products. The degree of integration of a two-dimensional (2D) memory device is mainly determined by the area occupied by a unit memory cell and is thus significantly affected by the level of fine pattern formation technology. However, expensive equipment is used to form fine patterns in a limited area of chip dies, thereby making it difficult to increase the degree of integration of 2D memory devices.

### SUMMARY

The present disclosure relates to a semiconductor device and a method of manufacturing the semiconductor device, which may improve a process variation of a vertical memory device having a three-dimensional structure including a contact plug with a high aspect ratio, and at the same time, may improve electrical characteristics of a device.

Also, the objectives of the present disclosure are not limited to the aforementioned objectives, but other objectives not described herein will be clearly understood by those skilled in the art from the following description.

In order to achieve the technical objectives, the present disclosure provides a semiconductor device as follows.

In some implementations, a semiconductor device includes a plurality of conductive line structures extending in a horizontal direction above a semiconductor substrate and overlapping each other in a vertical direction, wherein the semiconductor substrate includes a memory cell region and a connection region, a plurality of insulating layers each located between respective conductive line structures and extending in the horizontal direction, a plurality of channel structures extending in the vertical direction through the plurality of conductive line structures and the plurality of insulating layers in the memory cell region, and a plurality of plug structures having different heights in the connection region, extending in the vertical direction, and respectively corresponding to the plurality of conductive line structures, wherein the plurality of channel structures each include a ferroelectric layer, a channel-side dielectric layer, a channel layer, and an insulating plug, which are sequentially stacked in a direction from the plurality of conductive line structures toward a center of the channel structure, and the plurality of plug structures each include a contact plug, a plug barrier layer surrounding a lower surface and a side surface of the contact plug, and a spacer partially surrounding a sidewall of the plug barrier layer.

In some implementations, a semiconductor device includes a semiconductor substrate having a memory cell region and a connection region adjacent to the memory cell region, a gate stack including a plurality of conductive line structures and a plurality of insulating layers extending in a first direction and a second direction intersecting each other and parallel to a main surface of the semiconductor substrate and stacked alternately in a third direction perpendicular to the main surface of the semiconductor substrate, a channel structure located in the memory cell region and extending through the gate stack in the third direction, and a plurality of plug structures arranged in a stepped configuration in the connection region, wherein first ends of the plurality of plug structures are coplanar with each other, and second ends of the plurality of plug structures, opposite to the first ends, are respectively connected to corresponding conductive line structures among the plurality of conductive line structures, wherein the channel structure has a structure in which a channel layer, a channel-side dielectric layer, and a ferroelectric layer sequentially surround a lower surface and a side surface of an insulating plug in a 'U' shape, the plurality of conductive line structures each include a buried conductive layer, a conductive barrier layer surrounding an outer surface of the buried conductive layer, a first gate insulating layer surrounding an outer surface of the conductive barrier layer, and a second gate insulating layer surrounding an outer surface of the first gate insulating layer, and a spacer formed on a sidewall of each of the plug structures is in contact with an upper surface of the second gate insulating layer of the conductive line structure corresponding to the plug structure, and the second end of the plug structure extends to the buried conductive layer of the conductive line structure corresponding to the plug structure.

In some implementations, a semiconductor device includes a semiconductor substrate having a memory cell region and a connection region adjacent to the memory cell region, a gate stack including a plurality of conductive line structures and a plurality of insulating layers extending in a first direction and a second direction intersecting each other and parallel to a main surface of the semiconductor substrate and stacked alternately in a third direction perpendicular to the main surface of the semiconductor substrate, a channel structure located in the memory cell region and extending through the gate stack in the third direction, a bit line extending in the second direction at a higher vertical level than the channel structure and electrically connected to the channel structure, and a plurality of plug structures arranged in a stepped configuration in the connection region, wherein first ends of the plurality of plug structures are coplanar with each other, and second ends of the plurality of plug structures, opposite to the first ends, are respectively connected to corresponding conductive line structures among the plurality of conductive line structures, wherein the channel structure has a structure in which a channel layer, a channel-side dielectric layer, and a ferroelectric layer sequentially surround a lower surface and a side surface of an insulating plug in a 'U' shape, the plurality of conductive line structures each include a buried conductive layer, a conductive barrier layer surrounding an outer surface of the buried conductive layer, a first gate insulating layer including silicon oxide and surrounding an outer surface of the conductive barrier layer, and a second gate insulating layer including a high-k material and surrounding an outer surface of the first gate insulating layer, the plurality of plug structures each include a contact plug, a plug barrier layer surrounding a lower surface and a side surface of the contact plug, and a spacer partially surrounding a sidewall of the plug barrier layer, and the second end of the plug structure extends to the buried conductive layer of the conductive line structure corresponding to the plug structure, and the spacer is in contact with an upper surface of the second gate insulating layer of the conductive line structure corresponding to the plug structure.

### BRIEF DESCRIPTION OF THE DRAWINGS

Implementations will be more clearly understood from the following detailed description taken in conjunction with the accompanying drawings.

FIG. 1 is a block diagram showing an example of a semiconductor device.

FIG. 2 is an equivalent circuit diagram of an example of a memory cell array of a semiconductor device.

FIG. 3 is a plan view showing example components of a semiconductor device.

FIG. 4 is an example cross-sectional view of a semiconductor device taken along line A-A' in FIG. 3.

FIG. 5 is an example enlarged view of region EX1 in FIG. 4.

FIG. 6 is an example cross-sectional view of a semiconductor device taken along line B-B' in FIG. 5.

FIG. 7 is an example enlarged view of region EX2 in FIG. 4.

FIG. 8 is an example enlarged view of region EX3 in FIG. 4.

FIG. 9 is an example enlarged view of region EX2 in FIG. 4.

FIG. 10 is an example enlarged view of region EX2 in FIG. 4.

FIGS. 11A, 11B, 11C, 11D, 11E, 11F, and 11G are enlarged cross-sectional views showing an example of a method of manufacturing region EX1 of a semiconductor device in a process order,

FIGS. 12A, 12B, 12C, 12D, 12E, 12F, 12G, 12H, 12I, and 12J are enlarged cross-sectional views showing an example of a method of manufacturing region EX3 of a semiconductor device in a process order.

### DETAILED DESCRIPTION

Hereinafter, implementations are described in detail with reference to the accompanying drawings. The same reference numerals are given to the same elements in the drawings, and repeated descriptions thereof are omitted.

Since the implementation may be diversely modified and have various examples, specific implementations are illustrated in the drawings and described in detail in the detailed description. However, this is not intended to limit the scope of the present disclosure to the specific implementations, and it should be understood that the present disclosure covers all the modifications, equivalents, and replacements within the idea and technical scope disclosed herein. In describing the implementations, when it is determined that a detailed description of the related known art may obscure the gist of the present disclosure, the detailed description thereof is omitted.

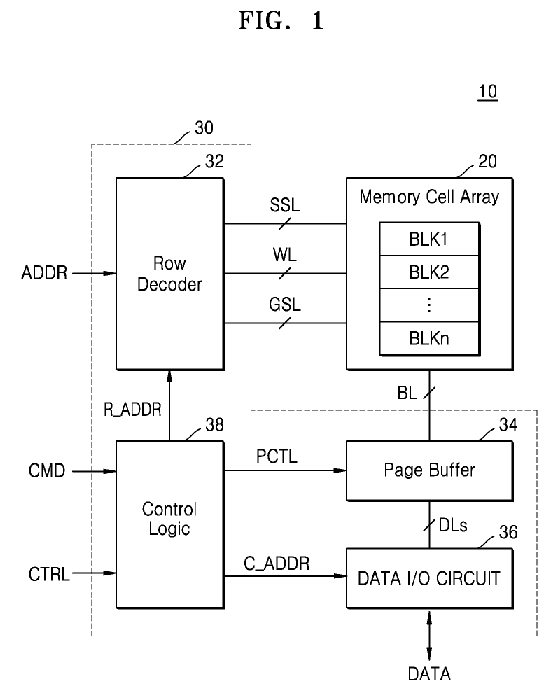

FIG. 1 is a block diagram showing an example of a semiconductor device 10.

Referring to FIG. 1, the semiconductor device 10 may include a memory cell array 20 and a peripheral circuit 30.

The memory cell array 20 includes a plurality of memory cell blocks BLK1, BLK2, …, and BLKn. Each of the plurality of memory cell blocks BLK1, BLK2, …, and BLKn may include a plurality of memory cells. The memory cell blocks BLK1, BLK2, …, and BLKn may be connected to the peripheral circuit 30 via a bit line BL, a word line WL, a string selection line SSL, and a ground selection line GSL.

The memory cell array 20 may be connected to the page buffer 34 via the bit line BL and connected to the row decoder 32 via the word line WL, the string selection line SSL, and the ground selection line GSL. In the memory cell array 20, the plurality of memory cells in the plurality of memory cell blocks BLK1, BLK2, …, and BLKn may each include a flash memory cell. The memory cell array 20 may include a three-dimensional (3D) memory cell array. The 3D memory cell array may include a plurality of NOT-AND (NAND) strings, and each of the NAND strings may include a plurality of memory cells connected to a plurality of word lines WL that are vertically stacked.

The peripheral circuit 30 may include a row decoder 32, a page buffer 34, a data input/output circuit 36, and a control logic 38. Although not shown, the peripheral circuit 30 may further include various circuits, such as a voltage generation circuit for generating various voltages required for operations of the semiconductor device 10, an error correction circuit for correcting errors in data read from the memory cell array 20, and an input/output interface.

The peripheral circuit 30 may receive an address ADDR, a command CMD, and a control signal CTRL from the outside of the semiconductor device 10 and may transmit data DATA to or receive the data DATA from a device external to the semiconductor device 10.

The configuration of the peripheral circuit 30 is described in detail below.

The row decoder 32 may select at least one of the pluralities of memory cell blocks BLK1, BLK2, …, and BLKn in response to an address ADDR from the outside of the row decoder 32 and may select the word line WL, the string selection line SSL, and the ground selection line GSL of the selected memory cell block. The row decoder 32 may transmit a voltage for performing a memory operation to the word line WL of the selected memory cell block.

The page buffer 34 may be connected to the memory cell array 20 via the bit line BL. The page buffer 34 may operate as a write driver during a program operation and apply a voltage to the bit line BL according to the data DATA to be stored in the memory cell array 20, and the page buffer 34 may operate as a sense amplifier during a read operation and sense the data DATA stored in the memory cell array 20. The page buffer 34 may operate according to a control signal PCTL provided from the control logic 38.

The data input/output circuit 36 may be connected to the page buffer 34 via data lines DLs. The data input/output circuit 36 may receive data DATA from a memory controller during the program operation and may provide program data DATA to the page buffer 34 on the basis of a column address C_ADDR provided from the control logic 38. The data input/output circuit 36 may provide the memory controller with read data DATA, stored in the page buffer 34, during the read operation on the basis of the column address C_ADDR provided from the control logic 38. The data input/output circuit 36 may transmit an input address or command to the control logic 38 or the row decoder 32.

The control logic 38 may receive a command CMD and a control signal CTRL from the memory controller. The control logic 38 may provide a row address R_ADDR to the row decoder 32 and provide the column address C_ADDR to the data input/output circuit 36. In response to the control signal CTRL, the control logic 38 may generate various internal control signals used inside the semiconductor device 10. For example, the control logic 38 may adjust a voltage level provided to the word line WL and the bit line BL, when performing memory operations, such as a program operation and an erase operation.

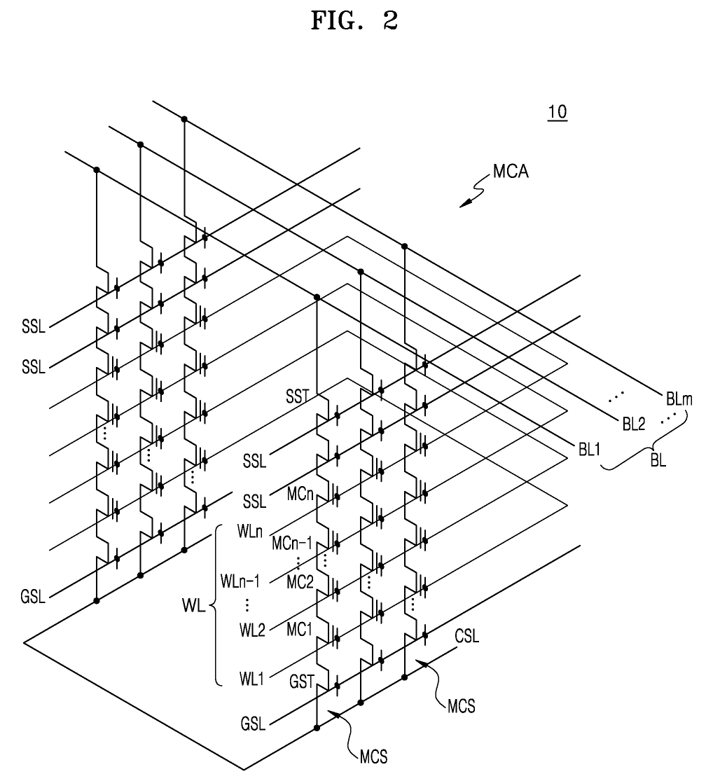

FIG. 2 is an equivalent circuit diagram of an example of a memory cell array of the semiconductor device 10.

Referring to FIG. 2, an example of an equivalent circuit diagram of a vertical NAND flash memory device having a vertical channel structure is shown.

In the semiconductor device 10 according to the present disclosure, a memory cell array MCA may include a plurality of memory cell strings MCS. The memory cell array MCA may include a plurality of bit lines BL, a plurality of word lines WL, at least one string selection line SSL, at least one ground selection line GSL, and a common source line CSL.

The plurality of memory cell strings MCS may be formed between the plurality of bit lines BL and the common source lines CSL. The diagram shows an example in which each of the plurality of memory cell strings MCS includes two string selection lines SSL, but the present disclosure is not limited thereto. For example, each of the plurality of memory cell strings MCS may include one string selection line SSL.

Each of the plurality of memory cell strings MCS may include a string selection transistor SST, a ground selection transistor GST, and a plurality of memory cell transistors MC1, MC2, …, MCn-1, and MCn. The drain region of the string selection transistor SST may be connected to the bit line BL, and the source region of the ground selection transistor GST may be connected to the common source line CSL. The common source line CSL may have a region to which source regions of a plurality of ground selection transistors GST are connected in common.

The string selection transistor SST may be connected to the string selection line SSL and the ground selection transistor GST may be connected to the ground selection line GSL. The plurality of memory cell transistors MC1, MC2, …, MCn-1, and MCn may be respectively connected to the plurality of word lines WL.

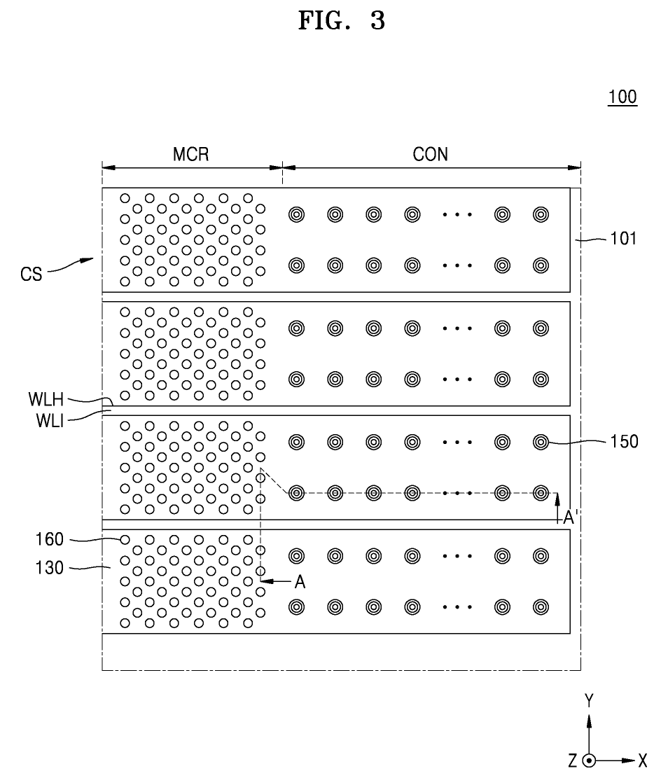

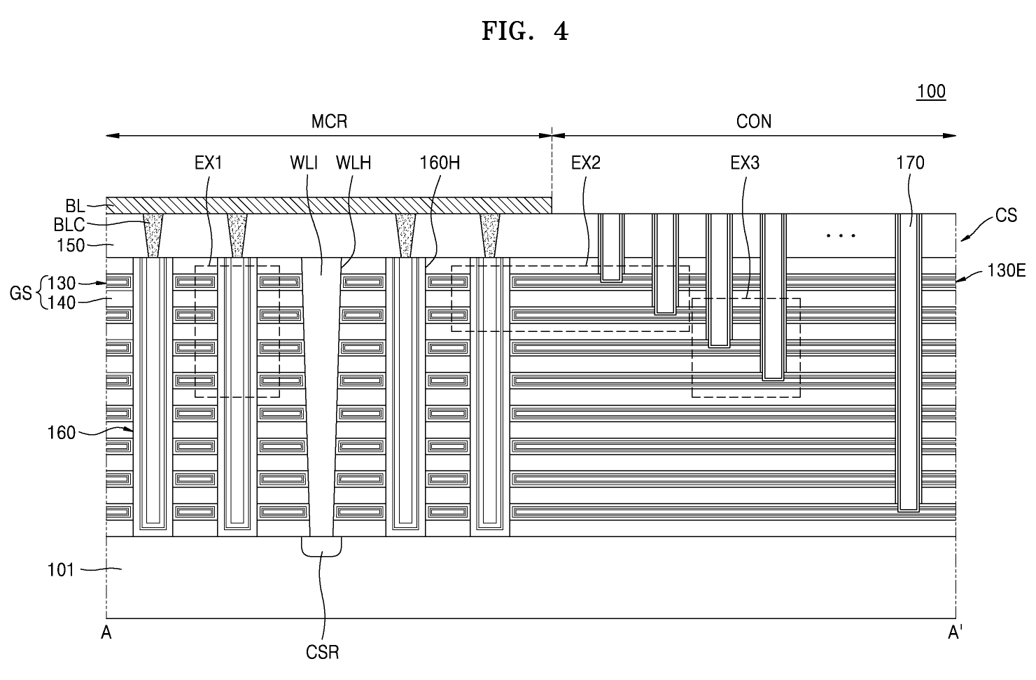

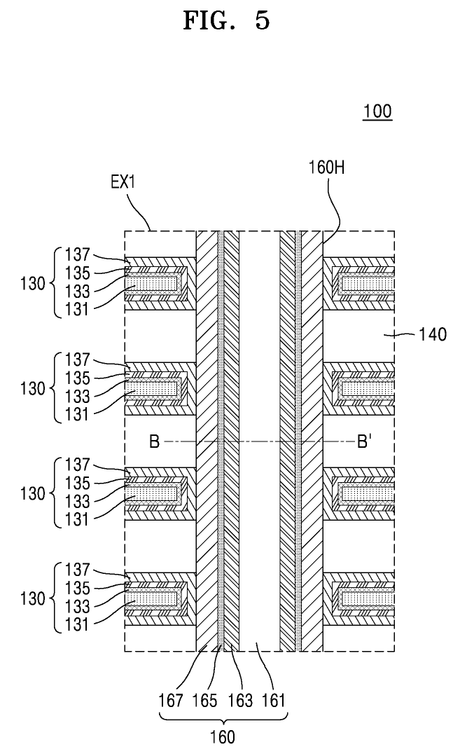

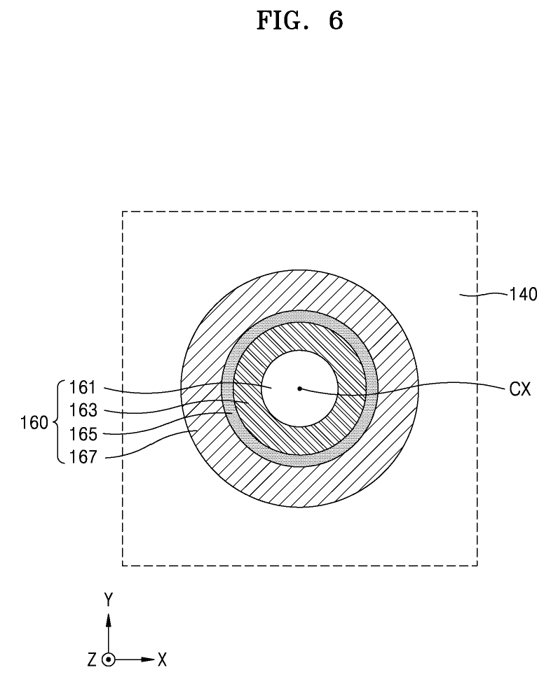

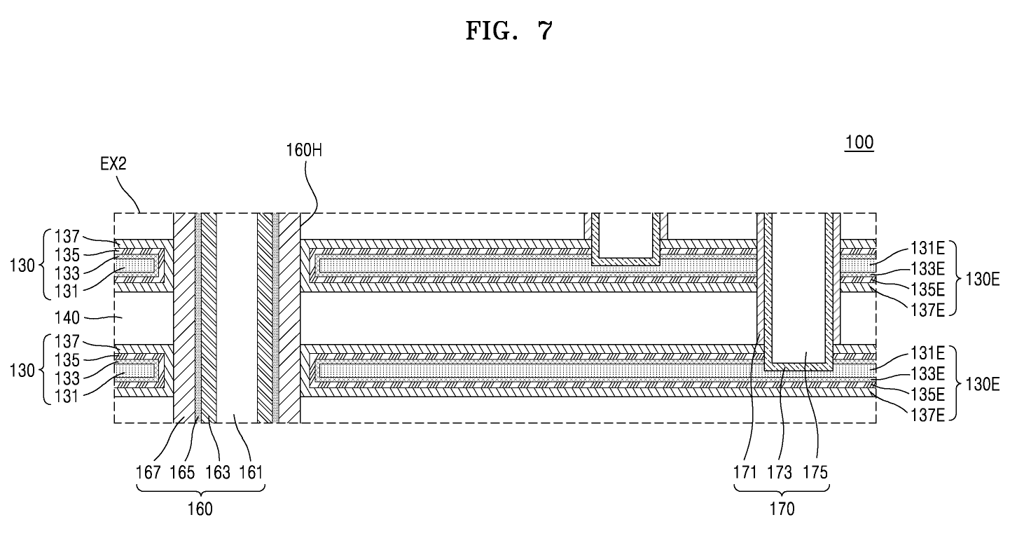

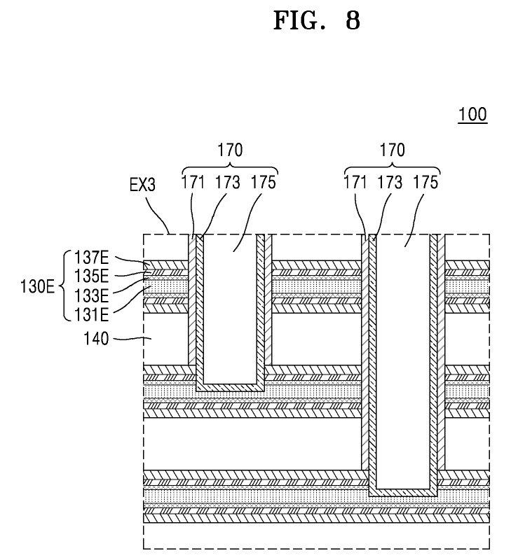

FIG. 3 is a plan view showing example components of a semiconductor device 100, and FIG. 4 is an example cross-sectional view of the semiconductor device 100 taken along line A-A' in FIG. 3. FIG. 5 is an example enlarged view of region EX1 in FIG. 4, FIG. 6 is an example cross-sectional view of the semiconductor device 100 taken along line B-B' in FIG. 5, FIG. 7 is an example enlarged view of region EX2 in FIG. 4, and FIG. 8 is an example enlarged view of region EX3 in FIG. 4.

Referring to FIGS. 3 to 8 together, the semiconductor device 100 may include a cell array structure CS that includes a memory cell region MCR and a connection region CON.

The memory cell region MCR may include a region in which an NAND-type memory cell array MCA having a vertical channel structure described with reference to FIG. 2 is formed. The connection region CON may have a region for electrically connecting the memory cell array MCA formed in the memory cell region MCR to a peripheral circuit region.

A semiconductor substrate 101 may include a semiconductor material, for example, a group IV semiconductor, a group III-V compound semiconductor, or a group II-VI oxide semiconductor. For example, the group IV semiconductor may include silicon (Si), germanium (Ge), or silicon-germanium. The semiconductor substrate 101 may be provided as a bulk wafer or a wafer having an epitaxial layer formed thereon. In some implementations, the semiconductor substrate 101 may include a silicon on insulator (SOI) substrate or a germanium on insulator (GeOI) substrate.

The gate stack GS may extend, on the semiconductor substrate 101, in a first direction (an X direction) and a second direction (a Y direction) parallel to a main surface of the semiconductor substrate 101. The gate stack GS may include a plurality of conductive line structures 130 and a plurality of insulating layers 140, and the plurality of conductive line structures 130 and the plurality of insulating layers 140 may be alternately arranged in the third direction (the Z direction) perpendicular to the upper surface of the semiconductor substrate 101. In addition, an upper insulating layer 150 may be disposed on the uppermost side of the gate stack GS.

In some implementations, the plurality of conductive line structures 130 may each include a buried conductive layer 131, a pair of conductive barrier layers 133, a pair of first gate insulating layers 135, and a pair of second gate insulating layers 137. Hereinafter, the first and second gate insulating layers 135 and 137 may be collectively referred to as the gate insulating layers 135 and 137.

Specifically, the pair of conductive barrier layers 133 may be disposed above and below the buried conductive layer 131, respectively, and in contact with the buried conductive layer 131. The second gate insulating layers 137 may be formed above the upper surface of a conductive barrier layer 133 at a relatively high vertical level among the pair of conductive barrier layers 133 and below the lower surface of a conductive barrier layers 133 at a relatively low vertical level among the pair of conductive barrier layers 133, and the first gate insulating layer 135 may be located between the conductive barrier layer 133 and the second gate insulating layer 137.

In some implementations, the buried conductive layer 131 may include metal, such as tungsten, metal silicide, such as tungsten silicide, doped polysilicon, or a combination thereof. In some implementations, the conductive barrier layer 133 may include titanium nitride, but the present disclosure is not limited thereto. In some implementations, the first gate insulating layer 135 may include silicon oxide, and the second gate insulating layer 137 may include a high-k material. Specifically, the second gate insulating layer 137 may include at least one selected from a group consisting of hafnium oxide, aluminum oxide, and a combination thereof.

The buried conductive layers 131 in the plurality of conductive line structures 130 may correspond to the ground selection line GSL, the word line WL, and the at least one string selection line SSL that constitute the memory cell string MCS described above with reference to FIG. 2. For example, the buried conductive layer 131 located lowermost may function as the ground selection line GSL, the buried conductive layer 131 located uppermost may function as the string selection line SSL, and the remaining buried conductive layers 131 may function as the word lines WL. Accordingly, the memory cell string MCS may be provided, in which the ground selection transistor GST, the string selection transistor SST, and the memory cell transistors MC1, MC2, …, MCn-1, and MCn between the ground selection transistor GST and the string selection transistor SST are connected to each other in series.

Above the semiconductor substrate 101, a plurality of word line cuts WLI may extend inside a word line cut opening WLH in the first direction (the X direction). The word line cuts WLI may each include an insulating structure. The gate stack GS located between a pair of word line cuts WLI may constitute a single block, and the pair of word line cuts WLI may define the width of the gate stack GS in the second direction (the Y direction). A plurality of common source regions CSR may be formed in the semiconductor substrate 101. The plurality of common source regions CSR may include impurity regions that are doped with impurities at high concentrations. The word line cut WLI may have a tapered shape of which the horizontal width decreases in the third direction (the Z direction) from an upper region to a lower region thereof.

A plurality of channel structures 160 may extend in the third direction (the Z direction) from the upper surface of the semiconductor substrate 101 in the memory cell region MCR while passing through the conductive line structure 130. A plurality of channel structures 160 may be spaced apart from each other by certain intervals in the first direction (the X direction) and the second direction (the Y direction). The plurality of the channel structures 160 may be arranged in a zigzag pattern or a staggered pattern.

The plurality of channel structures 160 may extend inside channel holes 160H that pass through the gate stack GS. The plurality of channel structures 160 may each include a ferroelectric layer 167, a channel-side dielectric layer 165, a channel layer 163, and an insulating plug 161, which are stacked in this order in the direction from the plurality of conductive line structures 130 toward a center CX of the channel structure 160.

For example, the plurality of channel structures 160 may have a cross-section in the form of a plurality of rings (see FIG. 6) in which the channel layer 163, the channel-side dielectric layer 165, and the ferroelectric layer 167 sequentially surround the insulating plug 161. For example, the insulating plug 161, the channel layer 163, the channel-side dielectric layer 165, and the ferroelectric layer 167 may have a concentric circular shape in a plan view. However, the technical idea of the present disclosure is not limited thereto, and for example, the insulating plug 161, the channel layer 163, the channel-side dielectric layer 165, and the ferroelectric layer 167 may have a concentric quadrangular shape, a concentric elliptical shape, etc.

Also, the plurality of channel structures 160 may be in contact with the semiconductor substrate 101. In some implementations, the ferroelectric layer 167 may be in contact with the upper surface of the semiconductor substrate 101 at the bottom of the channel hole 160H. In some implementations, the inner wall of the channel hole 160H may be completely covered by the ferroelectric layer 167, the inner wall of the ferroelectric layer 167 may be completely covered by the channel-side dielectric layer 165, the inner wall of the channel-side dielectric layer 165 may be covered by the channel layer 163, and the insulating plug 161 may be located in a column-shaped space defined by the channel layer 163 and surrounded by the channel layer 163. That is, the channel layer 163, the channel-side dielectric layer 165, and the ferroelectric layer 167 included in the channel structure 160 may have respective cross-sections that sequentially surround the bottom surface and side surfaces of the insulating plug 161 in a 'U' shape.

In some implementations, the insulating plug 161 may include silicon oxide, but the implementation is not limited thereto. Although not shown in the drawings of the present specification, in some implementations, the insulating plug 161 may include a seam, which is a hollow space, in the central region thereof.

In some implementations, the channel layer 163 may include polysilicon, an oxide semiconductor, a two-dimensional (2D) semiconductor material, or a combination thereof. The polysilicon may include doped polysilicon, but the implementation is not limited thereto.

In some implementations, the oxide semiconductor that may be used to form the channel layer 163 may be selected from a group consisting of InGaZnO (IGZO), Sn-IGZO, InWO (IWO), InZnO (IZO), ZnSnO (ZTO), ZnO, yttrium-doped zinc oxide (YZO), InGaSiO (IGSO), InO, SnO, TiO, ZnON, MgZnO, ZrInZnO, HfInZnO, SnInZnO, SiInZnO, GaZnSnO, ZrZnSnO, and a combinations thereof. In some implementations, the channel layer 163 may at least partially include the same elements as those constituting the oxide semiconductor layer and may further include at least one dopant selected from a group consisting of aluminum (Al), boron (B), arsenic (As), fluorine (F), and hydrogen (H).

In some implementations, the 2D semiconductor material that may be used to form the channel layer 163 may be selected from a group consisting of graphene, black phosphorous, a transition metal chalcogenide, and a combination thereof. The transition metal chalcogenide may include a combination of a transition metal selected from a group consisting of Ni, Cu, Zn, Mo, W, Nb, V, Ta, Ti, Zr, Hf, Tc, and Re, and a chalcogen element selected from a group consisting of S, Se, and Te. For example, the channel layer 163 may include MoS₂, MoSe₂, MoTe₂, WS₂, WSe₂, WTe₂, ZrS₂, ZrSe₂, HfS₂, HfSe₂, NbSe₂, ReSe₂, CuS, or a combination thereof, but the implementation is not limited thereto.

In some implementations, the 2D semiconductor material that may be used to form the channel layer 163 may include a chalcogenide material that includes a non-transition metal. The non-transition metal may be selected from a group consisting of Ga, In, Sn, Ge, and Pb. For example, the channel layer 163 may include SnSe₂, GaS, GaSe, GaTe, GeSe, In₂Se₃, InSnS₂, or a combination thereof, but the implementation is not limited thereto.

In some implementations, the channel layer 163 may include a p-type oxide semiconductor, an n-type oxide semiconductor, or a combination thereof. The p-type oxide semiconductor may be selected from a group consisting of nickel oxide (NiO), copper oxide, tin oxide (SnO), copper aluminum oxide (CuAlO₂), copper chromium oxide (CuCrO₂), β-TeO₂ (beta tellurium dioxide), and a combination thereof. The copper oxide may include CuO or Cu₂O, but the implementation is not limited thereto. The n-type oxide semiconductor may be selected from a group consisting of indium oxide (In₂O₃), tin oxide (SnO₂), zinc oxide (ZnO), IGZO, and a combination thereof. The tin oxide may exhibit p-type characteristics when existing in the form of SnO and may exhibit n-type characteristics when existing in the form of SnO₂.

In some implementations, the channel-side dielectric layer 165 may include silicon oxide, silicon oxynitride, a high-k dielectric material having a dielectric constant higher than the silicon oxide, or a combination thereof. The high-k dielectric material may include metal oxide. The high-k dielectric material may include an Al₂O₃ layer, but the implementation is not limited thereto.

In some implementations, the ferroelectric layer 167 may include at least one oxide selected from a group consisting of Hf, Si, Al, Zr, Y, La, Gd, and Sr. For example, the ferroelectric layer 167 may include hafnium oxide (HfO), hafnium zirconium oxide (HZO), hafnium titanium oxide, or hafnium silicon oxide. The term "HfO" as used herein represents a material composed of elements included in each of the terms and is not a chemical formula representing a stoichiometric relationship. For example, the ferroelectric layer 167 may include an HfO₂ layer. The ferroelectric layer 167 may further include a dopant when necessary. The dopant may include at least one element selected from a group consisting of Si, Al, Zr, Y, La, Gd, Sc, Sr, Mg, and Ba, but the implementation is not limited thereto. In some implementations, the horizontal thickness of the channel structure 160 may be substantially constant in the third direction (the Z direction).

In some implementations, the horizontal thickness of the ferroelectric layer 167 may be greater than the horizontal thickness of the channel layer 163. As used herein, the horizontal thickness of an element that constitutes the channel structure 160 may represent the difference between the distance from the outer wall of the element to the center CX and the distance from the inner wall of the element to the center CX.

A plurality of conductive line structures 130 may extend in a horizontal direction in the memory cell region MCR and the connection region CON. The plurality of conductive line structures 130 arranged in the connection region CON may be referred to as conductive line structure extensions 130E. In the connection region CON, the plurality of conductive line structure extensions 130E may overlap each other in a vertical direction. For example, the plurality of conductive line structure extensions 130E at different vertical levels in the connection region CON may have the same width in the horizontal direction.

In some implementations, a buried conductive layer extension 131E, a conductive barrier layer extension 133E, a first gate insulating layer extension 135E, and a second gate insulating layer extension 137E, which are included in the plurality of conductive line structure extensions 130E, may be respectively and integrally connected to the buried conductive layer 131, the conductive barrier layer 133, the first gate insulating layer 135, and the second gate insulating layer 137, which are included in the plurality of conductive line structures 130. Each of these corresponding components forms substantially the same component.

The connection region CON may include the conductive line structure extensions 130E and a plurality of plug structures 170 having different lengths in the third direction (the Z direction). In some implementations, the plurality of plug structures 170 may be respectively in contact with the plurality of conductive line structure extensions 130E, and thus, one plug structure 170 may be in contact with and electrically connected to one corresponding conductive line structure extension 130E.

The plurality of plug structures 170 may extend in the third direction (the Z direction) through the upper insulating layer 150, the plurality of insulating layers 140, and the plurality of conductive line structure extensions 130E in the connection region CON. The upper surfaces of the plurality of plug structures 170 may all be at the same vertical level and may also be at the same vertical level as the upper surface of the upper insulating layer 150. The lower surfaces of the plurality of plug structures 170 may all be at different vertical levels, and, for example, the lower surfaces of the plurality of plug structures 170 may be respectively on corresponding conductive line structure extensions 130E.

The plurality of plug structures 170 may be spaced apart from each other by certain intervals in the first direction (the X direction) and the second direction (the Y direction). In some implementations, the plug structure 170 may include a spacer 171, a plug barrier layer 173, and a contact plug 175.

In some implementations, the plug barrier layer 173 may conformally surround the lower surface and side surfaces of the contact plug 175. That is, the contact plug 175 may be located inside a column-shaped space defined by the plug barrier layer 173 and surrounded by the plug barrier layer 173.

Referring to FIG. 8, In some implementations, the spacer 171 may conformally surround a portion of the sidewall of the plug barrier layer 173. The spacer 171 may be formed on both sidewalls of the plug barrier layer 173,= but may not be formed on at least a portion of the sidewalls of the plug barrier layer 173. That is, the spacer 171 may extend downward in the third direction (the Z direction) from the upper surface of the plug barrier layer 173 along the sidewall of the plug barrier layer 173 but does not extend to the vertical level of the lower surface of the plug barrier layer 173. The vertical levels of the lower surfaces of the spacers 171 may be respectively higher than the vertical levels of the lower surfaces of the corresponding plug barrier layers 173.

The plug barrier layer 173 and the contact plug 175 may extend at least partially inward from the upper surface of the corresponding conductive line structure extension 130E, but the spacer 171 may only come into contact with the upper surface of the corresponding conductive line structure extension 130E and may not extend into the conductive line structure extension 130E. That is, the lower surface of the spacer 171 may be coplanar with the upper surface of the corresponding conductive line structure extension 130E. Compared to the spacer 171, the plug barrier layer 173 and the contact plug 175 may have a shape that protrudes relatively vertically downward.

In the present specification, each sidewall of the plurality of plug structures 170 is illustrated as having a profile perpendicular to the upper surface of the substrate 101, but in some implementations, the plurality of plug structures 170 may each have a tapered column shape that decreases in width in the third direction (the Z direction) from an upper region to a lower region thereof.

Although not shown, a plurality of dummy channel structures that extend in the third direction (the Z direction) through the gate stack GS may be formed in the connection region CON. The dummy channel structure may prevent the gate stack GS from bending or warping during the manufacturing process of the semiconductor device 100, thereby providing structural stability.

A bit line contact BLC may pass through the upper insulating layer 150 and come into contact with the channel structure 160, and a bit line BL in contact with the bit line contact BLC may extend in the second direction (the Y direction) on the upper insulating layer 150. Although not shown herein, in some implementations, a plurality of bit line contact pads may be located between the plurality of channel structures 160 and a plurality of bit line contacts BLC.

In some implementations, the plurality of bit line contacts BLC and the plurality of bit lines BL may each include metal, conductive metal nitride, or a combination thereof. For example, the plurality of bit line contacts BLC and the plurality of bit lines BL may each include tungsten, titanium, tantalum, copper, aluminum, titanium nitride, tantalum nitride, tungsten nitride, or a combination thereof.

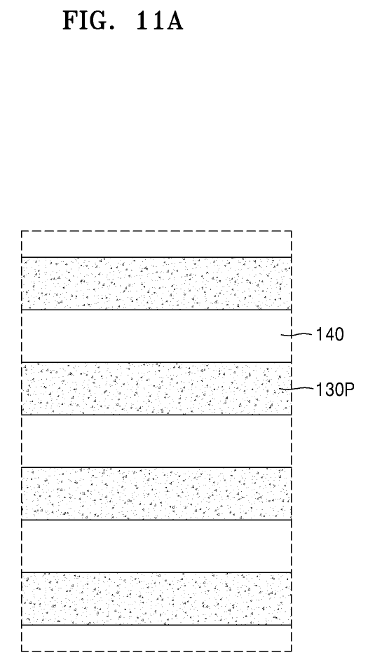

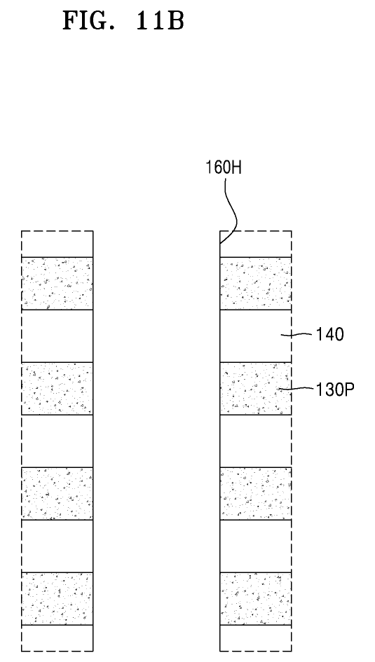

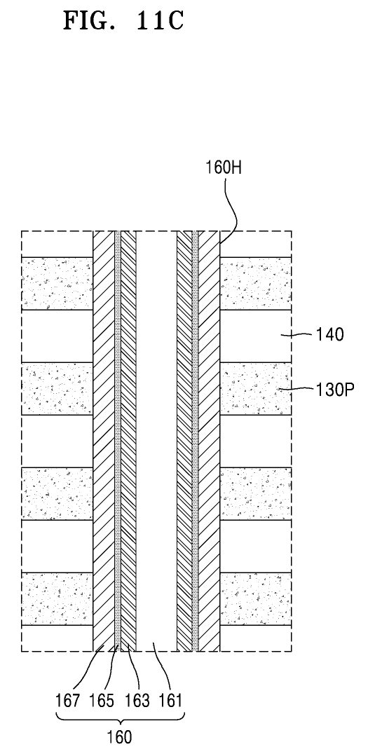

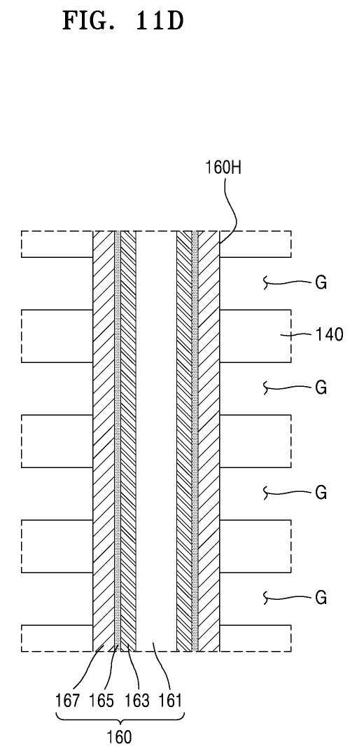

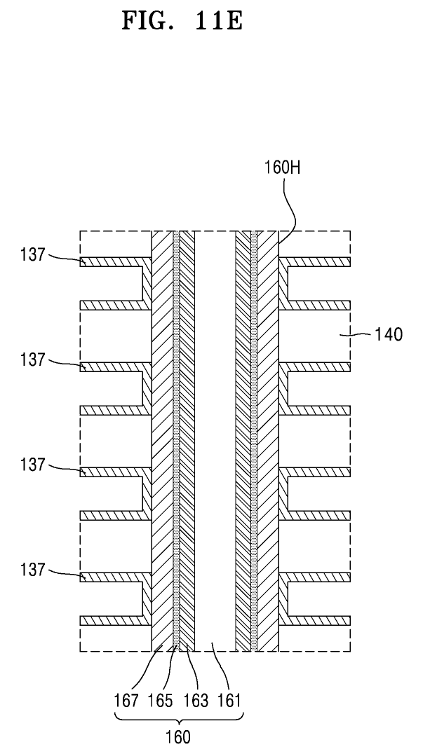

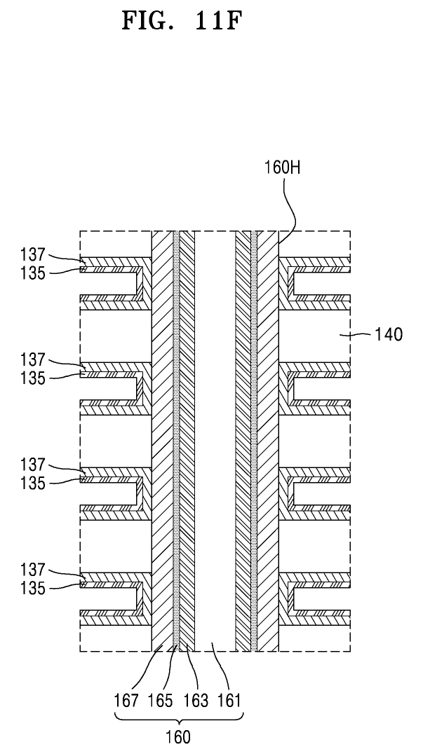

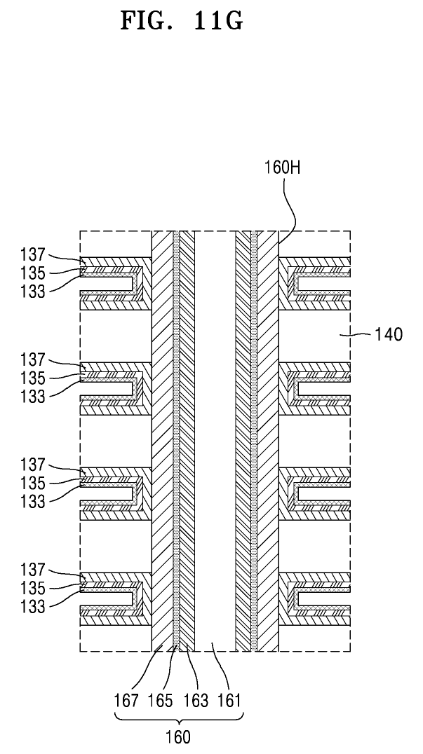

In the semiconductor device 100 according to the present disclosure, the gate insulating layers 135 and 137 may be provided in the conductive line structure 130 rather than in the channel structure 160. Therefore, in the manufacturing process of the semiconductor device 100, the gate insulating layers 135 and 137 are formed during processes of removing a sacrificial pattern 130P and forming the conductive line structure 130 at the location where the sacrificial pattern 130P was located (see FIGS. 11D to 11F), and thus, the gate insulating layers 135 and 137 having a small thickness may be easily deposited. The electrical characteristics of a device may be improved by making the gate insulating layers 135 and 137 thin. Also, the time-dependent dielectric breakdown (TDDB) characteristics of the device may be improved compared to when the gate insulating layers 135 and 137 are deposited in the channel structure 160.

Furthermore, the connection region CON of the semiconductor device 100 may include a stair-free contact structure. Accordingly, when performing a process of forming the plurality of plug structures 170 stacked in a stepped configuration in the connection region CON, the second gate insulating layer extension 137E including at least one of hafnium oxide, aluminum oxide, and a combination thereof may act as an etch stop layer, thereby reducing the process variation of the stair-free contact structure, even when the number of layers of word lines increases.

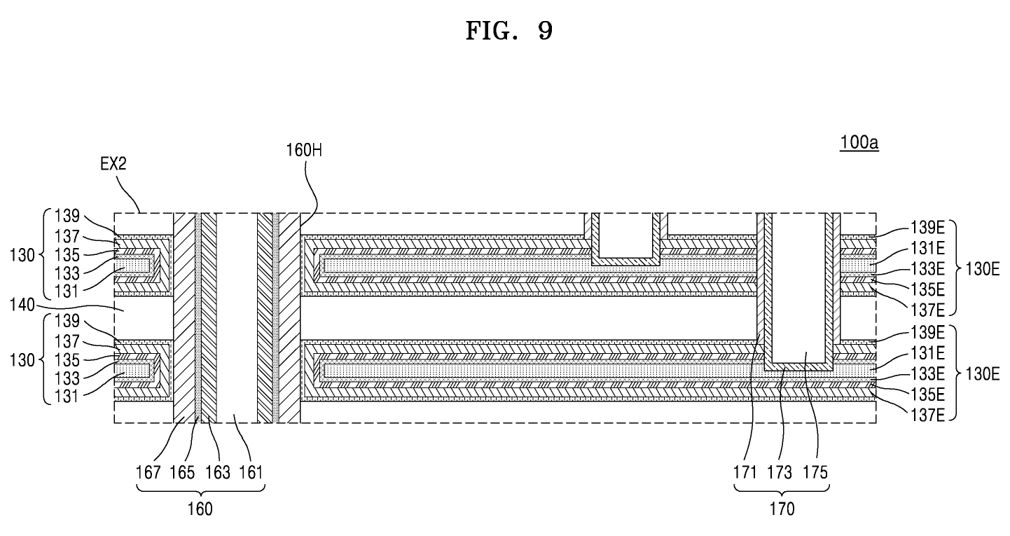

FIG. 9 is an example enlarged cross-sectional view showing a portion of a semiconductor device 100a. Specifically, the enlarged view in FIG. 9 may be an enlarged cross-sectional view of the semiconductor device 100a, in a region corresponding to region EX2 of the semiconductor device 100 in FIG. 4. It will be understood that the semiconductor device 100a of FIG. 9 is not mutually exclusive with the semiconductor device 100 described with reference to FIGS. 1 to 8, and elements having the same reference numerals represent the same components. Hereinafter, repeated descriptions of the same components are omitted, and the differences from the semiconductor device 100 of FIGS. 1 to 8 are mainly described.

Referring to FIG. 9, the conductive line structure 130 may include the buried conductive layer 131, the conductive barrier layer 133, the first gate insulating layer 135, the second gate insulating layer 137, and a third gate insulating layer 139. The conductive line structure extension 130E may include the buried conductive layer extension 131E, the conductive barrier layer extension 133E, the first gate insulating layer extension 135E, the second gate insulating layer extension 137E, and a third gate insulating layer extension 137E. That is, compared to the semiconductor device 100 including a double layer including the gate insulating layers 135 and 137 as described above with reference to FIGS. 1 to 8, the semiconductor device 100a in FIG. 9 may include a triple layer including gate insulating layers 135, 137, and 139 (or referred to as first to third gate insulating layers 135, 137, and 139).

In some implementations, the first gate insulating layer 135 may include silicon oxide. In some implementations, the second gate insulating layer 137 may include at least one selected from a group consisting of hafnium oxide, aluminum oxide, and a combination thereof, but the present disclosure is not limited thereto. In some implementations, the third gate insulating layer 139 may include at least one selected from a group consisting of SiON, SiN, SiO₂, and a combination thereof, but the present disclosure is not limited thereto.

The semiconductor device 100a includes the first to third gate insulating layers 135, 137, and 139 that are provided in the conductive line structure 130 rather than the channel structure 160. Therefore, the gate insulating layers 135, 137, and 139 having a small thickness may be easily deposited as described above with reference to the semiconductor device 100. The electrical characteristics of a device may be improved by making the gate insulating layers 135, 137, and 139 thin. Also, the TDDB characteristics of the device may be improved compared to when the gate insulating layers 135, 137, and 139 are deposited in the channel structure 160.

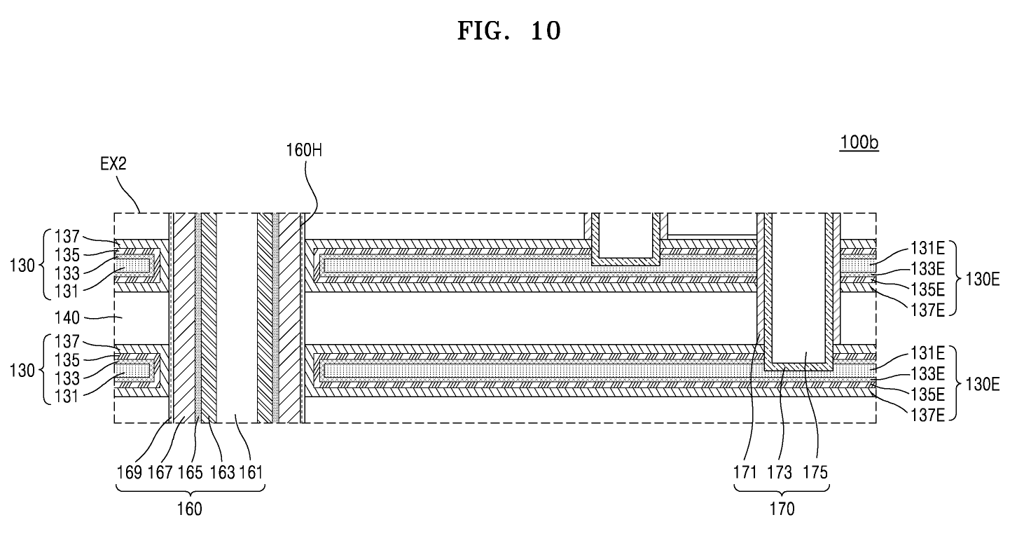

FIG. 10 is an example enlarged cross-sectional view showing a portion of a semiconductor device 100b. Specifically, the enlarged view in FIG. 10 may be an enlarged cross-sectional view of the semiconductor device 100b, in a region corresponding to region EX2 of the semiconductor device 100 in FIG. 4. It will be understood that the semiconductor device 100b of FIG. 10 is not mutually exclusive with the semiconductor device 100 described with reference to FIGS. 1 to 8, and elements having the same reference numerals represent the same components. Hereinafter, repeated descriptions of the same components are omitted, and the differences from the semiconductor device 100 of FIGS. 1 to 8 are mainly described.

Referring to FIG. 10, the conductive line structure 130 may include the buried conductive layer 131, the conductive barrier layer 133, the first gate insulating layer 135, and the second gate insulating layer 137. In addition, the channel structure 160 may include the insulating plug 161, the channel layer 163, the channel-side dielectric layer 165, the ferroelectric layer 167, a third gate insulating layer 169. That is, compared to the semiconductor device 100 in which the first and second gate insulating layers 135 and 137 are provided only in the conductive line structure 130 as described above with reference to FIGS. 1 to 8, the semiconductor device 100b in FIG. 10 may be configured such that the first and second gate insulating layers 135 and 137 are provided in the conductive line structure 130 and the third gate insulating layer 169 is provided in the channel structure 160.

In some implementations, the first gate insulating layer 135 may include silicon oxide. In some implementations, the second gate insulating layer 137 may include at least one selected from a group consisting of hafnium oxide, aluminum oxide, and a combination thereof, but the present disclosure is not limited thereto. In some implementations, the third gate insulating layer 169 may include at least one selected from a group consisting of SiON, SiN, SiO₂, and a combination thereof, but the present disclosure is not limited thereto.

In the semiconductor device 100b, the first and second gate insulating layers 135 and 137 among the first to third gate insulating layers 135, 137, and 169 (or referred to as the gate insulating layers 135, 137, and 169) are formed in the conductive line structure 130 rather than the channel structure 160. Therefore, the first and second gate insulating layers 135 and 137 having a small thickness may be easily deposited as described above with reference to the semiconductor device 100. The electrical characteristics of a device may be improved by making the first and second gate insulating layers 135 and 137 thin. Also, the TDDB characteristics of the device may be improved compared to when all the gate insulating layers 135, 137, and 169 are deposited in the channel structure 160.

FIGS. 11A, 11B, 11C, 11D, 11E, 11F, and 11G are enlarged cross-sectional views showing an example of a method of manufacturing the semiconductor device 100 in a process order. Specifically, FIGS. 11A, 11B, 11C, 11D, 11E, 11F, and 11G may be enlarged cross-sectional views of the semiconductor device 100, in a region corresponding to region EX1 (see FIGS. 4 and 5).

Referring to FIG. 11A, the plurality of insulating layers 140 and a plurality of sacrificial patterns 130P may be alternately stacked one by one on the substrate 101 (see FIG. 4) to form a stack structure. In some implementations, the material in the plurality of insulating layers 140 and the material in the plurality of sacrificial patterns 130P may have etch selectivity relative to each other.

Referring to FIGS. 11B and 11C, the channel hole 160H extending through the stack structure of FIG. 11A in the third direction (the Z direction) may be formed (see FIG. 11B), and the channel structure 160 filling the channel hole 160H may be formed.

-The forming of the channel structure 160 may include forming the ferroelectric layer 167 that conformally surrounds the sidewalls and bottom of the channel hole 160H, forming the channel-side dielectric layer 165 that conformally surrounds the exposed sidewalls and bottom of the ferroelectric layer 167, forming the channel layer 163 that conformally surrounds the exposed sidewalls and bottom of the channel-side dielectric layer 165, and forming the insulating plug 161 that fills the remaining space surrounded by the channel layer 163. The cross-section of the channel structure 160 formed by the processes described above may have a shape in which the ferroelectric layer 167, the channel-side dielectric layer 165, the channel layer 163, and the insulating plug 161 are sequentially stacked in a direction from the plurality of insulating layers 140 and the plurality of sacrificial patterns 130P toward the center CX of the channel structure 160, as described above with reference to FIG. 6.

In some implementations, atomic layer deposition (ALD), chemical vapor deposition (CVD), or a combination thereof may be used to form the ferroelectric layer 167, the channel-side dielectric layer 165, the channel layer 163, and the insulating plug 161, but the implementation is not limited to the examples described above. In addition, after forming the channel structure 160, a chemical mechanical polishing (CMP) process may be used to planarize the upper surface thereof.

Referring to FIG. 11D, a plurality of first gaps G may be formed by removing the plurality of sacrificial patterns 130P from the resulting structure shown in FIG. 11C.

In order to form the plurality of first gaps G, the word line cut opening WLH described above with reference to FIG. 4 may be formed in advance, and the plurality of sacrificial patterns 130P may be removed via the word line cut opening WLH. In order to remove plurality of sacrificial patterns 130P, for example, a wet etching process may be used. After the plurality of sacrificial patterns 130P are removed, the outer wall of the channel structure 160 may be partially exposed via the plurality of first gaps G. The plurality of insulating layers 140 may be spaced apart from each other in the third direction (the Z direction) with one of the pluralities of first gaps G therebetween.

Referring to FIG. 11E, the second gate insulating layer 137 may surround a portion of the outer wall of the channel structure 160 exposed by the plurality of first gaps G and the lower surface and the upper surface of each of the plurality of insulating layers 140. In some implementations, the second gate insulating layer 137 may include at least one selected from a group consisting of hafnium oxide, aluminum oxide, and a combination thereof.

Referring to FIG. 11F, in the result of FIG. 11E, the first gate insulating layer 135 may have a conformal thickness so as to cover the inner wall of a region surrounded by the second gate insulating layer 137. In some implementations, the first gate insulating layer 135 may include silicon oxide, but the present disclosure is not limited thereto.

Referring to FIG. 11G, in the result of FIG. 11F, the conductive barrier layer 133 may have a conformal thickness so as to cover the inner wall of a region surrounded by the first gate insulating layer 135. In some implementations, the conductive barrier layer 133 may include titanium nitride, but the present disclosure is not limited thereto.

Next, when the buried conductive layer 131 fills the space surrounded by the conductive barrier layer 133, the channel structure 160, which includes the insulating plug 161, the channel layer 163, the channel-side dielectric layer 165, and the ferroelectric layer 167, and the conductive line structure 130, which includes the buried conductive layer 131, the conductive barrier layer 133, the first gate insulating layer 135, and the second gate insulating layer 137, may be formed in the memory cell region MCR as illustrated in FIGS. 4 and 5.

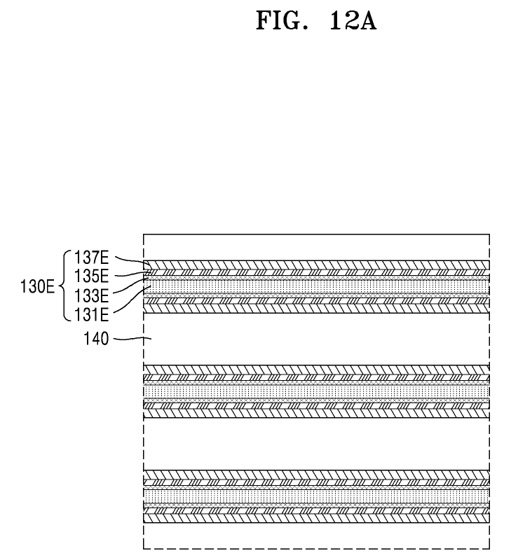

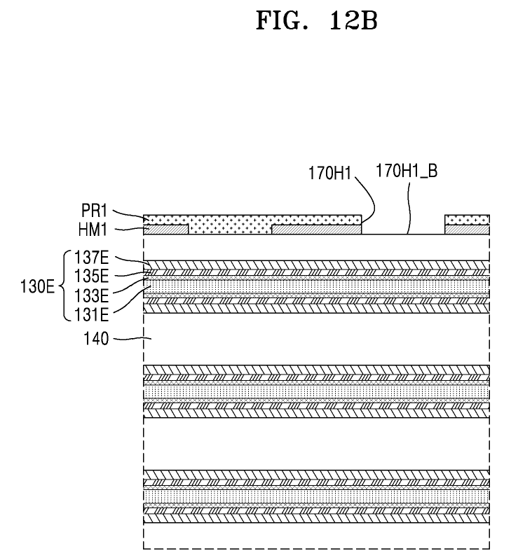

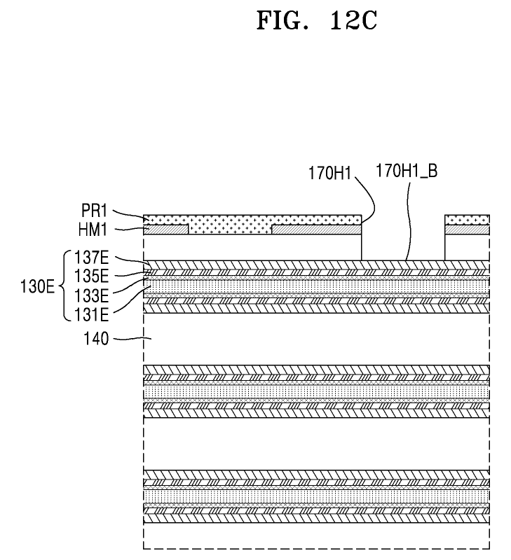

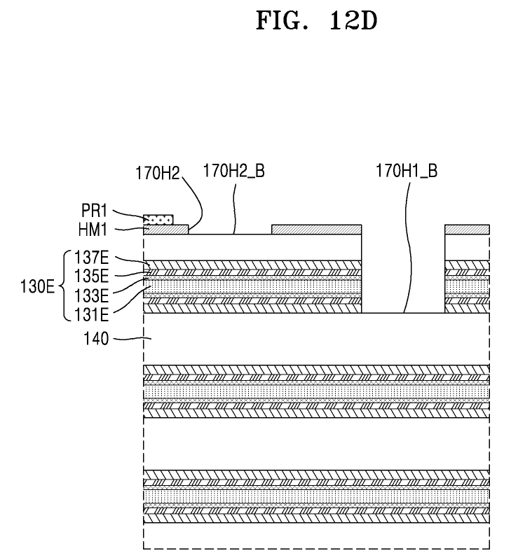

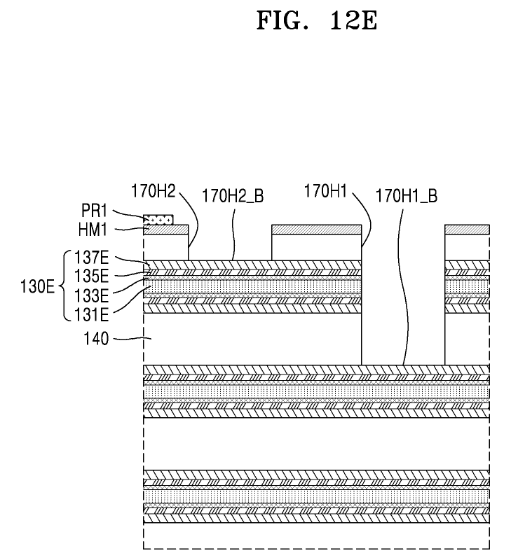

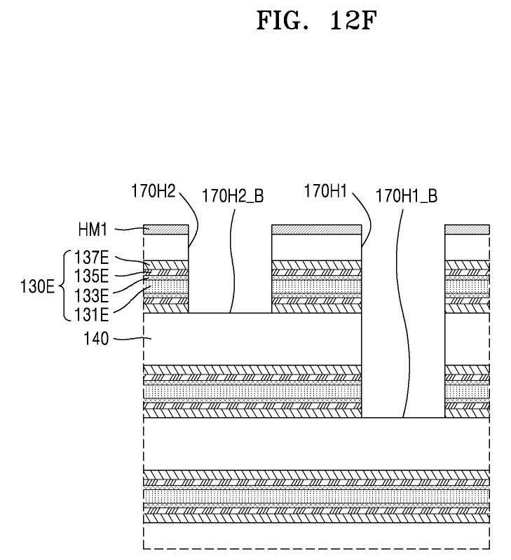

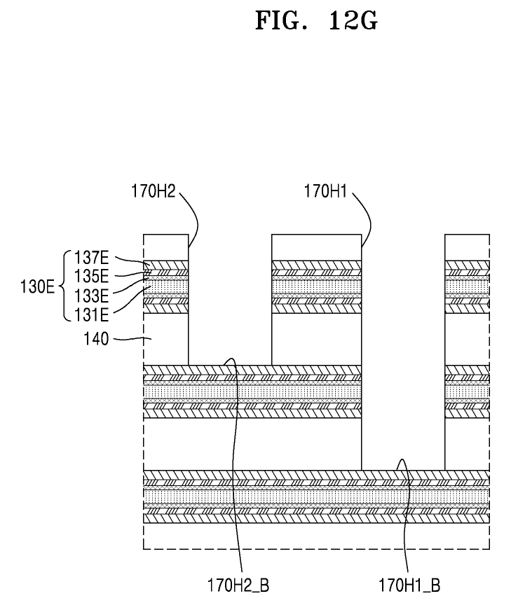

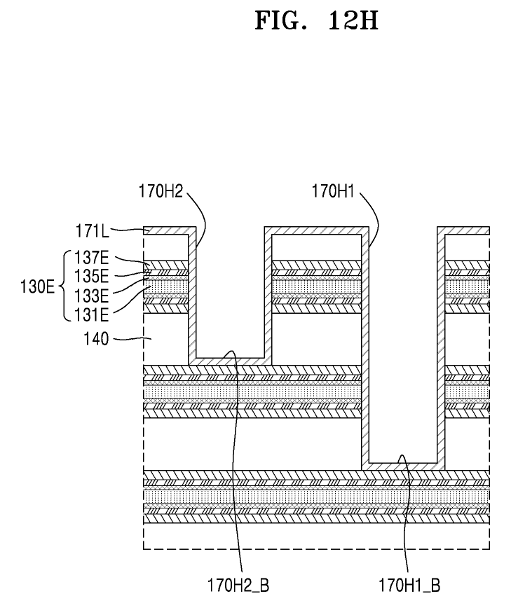

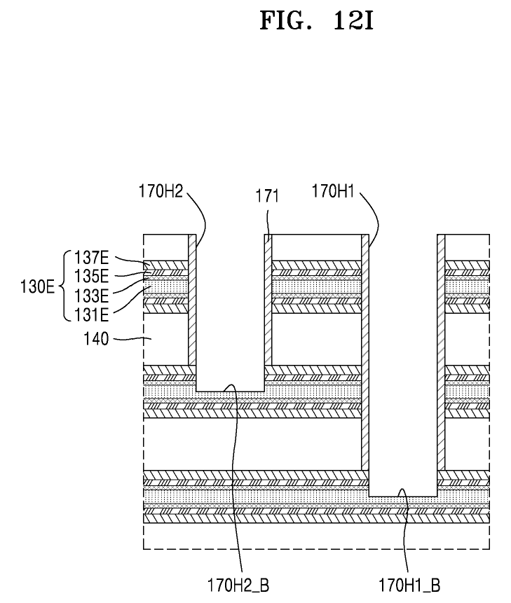

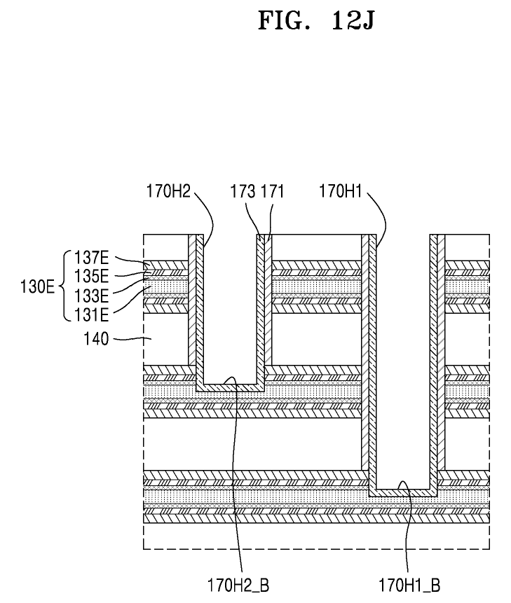

FIGS. 12A, 12B, 12C, 12D, 12E, 12F, 12G, 12H, 12I, 12J are enlarged cross-sectional views showing an example of a method of manufacturing the semiconductor device 100 in a process order. Specifically, FIGS. 12A, 12B, 12C, 12D, 12E, 12F, 12G, 12H, 12I, 12J may be enlarged cross-sectional views of the semiconductor device 100, in a region corresponding to region EX3 (see FIGS. 4 and 8).

Referring to FIG. 12A, a structure may be prepared in which the plurality of insulating layers 140 are alternately stacked with the plurality of conductive line structure extensions 130E that are formed by extending, to the connection region CON, the plurality of conductive line structures 130 described with reference to FIG. 11A and FIG. 11G. In some implementations, the plurality of conductive line structure extensions 130E may include the buried conductive layer extension 131E, the conductive barrier layer extension 133E, the first gate insulating layer extension 135E, and the second gate insulating layer extension 137E. Also, these components may respectively correspond to the buried conductive layer 131, the conductive barrier layer 133, the first gate insulating layer 135, and the second gate insulating layer 137 which are provided in the plurality of conductive line structures 130.

Referring to FIG. 12B, a first hard mask layer HM1 may be disposed on the insulating layer 140 located uppermost (or referred to as the uppermost insulating layer 140) among the plurality of insulating layers 140, and a first photoresist layer PR1 may be formed thereon. Subsequently, a photolithography process may be performed.

In some implementations, a first plug hole 170H1 may be formed by the photolithography process, and the upper surface of the uppermost insulating layer 140 may be partially exposed via the first plug hole 170H1. A lower surface 170H1_B of the first plug hole 170H1 may be coplanar with the upper surface of the uppermost insulating layer 140.

Referring to FIG. 12C, the uppermost insulating layer 140 exposed via the first plug hole 170H1 may be partially removed in the third direction (the Z direction). The process of partially removing the uppermost insulating layer 140 may continue to expose the upper surface of a second gate insulating layer extension 137E located at the top (hereinafter referred to as an upper second gate insulating layer extension 137E) among a pair of second gate insulating layer extensions 137E included in the conductive line structure extension 130E located uppermost (or referred to as the uppermost conductive line structure extension 130E). In some implementations, the process of partially removing the uppermost insulating layer 140 may include an etching process. In this case, the upper second gate insulating layer extension 137E may serve as an etch stop layer during the process described above. By this process, the lower surface 170H1_B of the first plug hole 170H1 may be coplanar with the upper surface of the upper second gate insulating layer extension 137E.

Referring to FIG. 12D, the first photoresist layer PR1 may be partially removed, and a second plug hole 170H2 may be formed by using the first hard mask layer HM1 as an etching mask. Also, during this process, the first plug hole 170H1 may extend to the lower surface of the uppermost conductive line structure extension 130E. That is, the lower surface 170H1_B of the first plug hole 170H1 may be coplanar with the lower surface of the uppermost conductive line structure extension 130E.

In some implementations, the upper surface of the uppermost insulating layer 140 may be partially exposed via the second plug hole 170H2. A lower surface 170H2_B of the second plug hole 170H2 may be coplanar with the upper surface of the uppermost insulating layer 140.

Referring to FIG. 12E, the first plug hole 170H1 and the second plug hole 170H2 may be etched to expose the lower surface of the insulating layer 140 that is positioned second from the top (hereinafter referred to as the second uppermost insulating layer 140) and the lower surface of the uppermost insulating layer 140, respectively. During the etching process, the second gate insulating layer extension 137E also acts as an etch stop layer. Therefore, the lower surface 170H1_B of the first plug hole 170H1 may be coplanar with the upper surface of the upper second gate insulating layer extension 137E included in the conductive line structure extension 130E that is positioned second from the top (hereinafter referred to as the second uppermost conductive line structure extension 130E), and the lower surface 170H2_B of the second plug hole 170H2 may be coplanar with the upper surface of the upper second gate insulating layer extension 137E included in the uppermost conductive line structure extension 130E.

Referring to FIG. 12F, the first plug hole 170H1 and the second plug hole 170H2 may be etched to the level of the lower surface of the second uppermost conductive line structure extension 130E and the level of the lower surface of the uppermost conductive line structure extension 130E, respectively. Therefore, the lower surface 170H1_B of the first plug hole 170H1 may be coplanar with the lower surface of the second uppermost conductive line structure extension 130E, and the lower surface 170H2_B of the second plug hole 170H2 may be coplanar with the lower surface of the uppermost conductive line structure extension 130E. Also, as shown in FIG. 12F, the first photoresist layer PR1 may be removed.

Referring to FIG. 12G, the first plug hole 170H1 and the second plug hole 170H2 may be etched to expose the lower surface of the insulating layer 140 that is positioned third from the top (hereinafter referred to as the third uppermost insulating layer 140) and the lower surface of the second uppermost insulating layer 140, respectively. During the etching process, the second gate insulating layer extension 137E also acts as an etch stop layer. Therefore, the lower surface 170H1_B of the first plug hole 170H1 may be coplanar with the upper surface of the upper second gate insulating layer extension 137E included in the conductive line structure extension 130E that is positioned third from the top (hereinafter referred to as the third uppermost conductive line structure extension 130E), and the lower surface 170H2_B of the second plug hole 170H2 may be coplanar with the upper surface of the upper second gate insulating layer extension 137E included in the second uppermost conductive line structure extension 130E.

Referring to FIG. 12H, the first hard mask layer HM1 disposed on the uppermost insulating layer 140 may be removed, and a preliminary spacer 171L may be formed on the resulting structure shown in FIG. 12G. The preliminary spacer 171L may completely cover the exposed surfaces of the insulating layer 140 and the conductive line structure extension 130E. In some implementations, the preliminary spacer 171L may have a conformal thickness. In some implementations, the preliminary spacer 171L may include oxide, but the present disclosure is not limited thereto.

Referring to FIG. 12I, an etch-back process is performed on the result shown in FIG. 12H to partially remove the preliminary spacer 171L (see FIG. 12H). As a result, the spacer 171 is left. The preliminary spacer 171L (see FIG. 12H) disposed on the uppermost insulating layer 140 may be removed together by the etch-back process, and thus, the upper surface of the uppermost insulating layer 140 may be exposed again. Also, the vertical heights of the lower surface 170H1_B of the first plug hole 170H1 and the lower surface 170H2_B of the second plug hole 170H2 may be lowered.

For example, the vertical level of the lower surface 170H1_B of the first plug hole 170H1 may be between the level of the lower surface of the buried conductive layer extension 131E of the third uppermost conductive line structure extension 130E and the level of the upper surface of the buried conductive layer extension 131E thereof. Also, the vertical level of the lower surface 170H2_B of the second plug hole 170H2 may be between the level of the lower surface of the buried conductive layer extension 131E of the second uppermost conductive line structure extension 130E and the level of the upper surface of the buried conductive layer extension 131E thereof. As a result, the lower surface 170H1_B of the first plug hole 170H1 may expose the buried conductive layer extension 131E of the third uppermost conductive line structure extension 130E, and the lower surface 170H2_B of the second plug hole 170H2 may expose the buried conductive layer extension 131E of the second uppermost conductive line structure extension 130E.

Referring to FIG. 12J, the plug barrier layer 173 may be formed in the resulting structure shown in FIG. 12I so as to surround the sidewalls and the bottom surfaces of the first plug hole 170H1 and the second plug hole 170H2. In some implementations, the plug barrier layer 173 may have a conformal thickness. In some implementations, the plug barrier layer 173 may include titanium nitride, but the present disclosure is not limited thereto.

Next, when the contact plug 175 fills all the remaining space surrounded by the plug barrier layer 173 in the first plug hole 170H1 and the second plug hole 170H2, the plug structure 170, which includes the spacer 171, the plug barrier layer 173, and the contact plug 175, may be formed in the connection region CON, as described with reference to FIGS. 4 and 8.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various changes in form and details may be made therein without departing from the spirit and scope of the following claims.

What is claimed is:

1. A semiconductor device comprising:
a plurality of conductive line structures extending in a horizontal direction above a semiconductor substrate, the plurality of conductive line structures overlapping each other in a vertical direction, wherein the semiconductor substrate comprises a memory cell region and a connection region;
a plurality of insulating layers, each insulating layer of the plurality of insulating layers being located between two neighboring conductive line structures of the plurality of conductive line structures, and the plurality of insulating layers extending in the horizontal direction;
a plurality of channel structures extending in the vertical direction through the plurality of conductive line structures and the plurality of insulating layers in the memory cell region; and
a plurality of plug structures having different heights in the connection region, the plurality of plug structures extending in the vertical direction, and the plurality of plug structures respectively corresponding to the plurality of conductive line structures,
wherein each channel structure of the plurality of channel structures comprises a ferroelectric layer, a channel-side dielectric layer, a channel layer, and an insulating plug that are sequentially stacked in a direction from the plurality of conductive line structures toward a center of the channel structure, and
wherein each plug structure of the plurality of plug structures comprises a contact plug, a plug barrier layer surrounding a lower surface and a side surface of the contact plug, and a spacer partially surrounding a sidewall of the plug barrier layer.

2. The semiconductor device of claim 1, wherein each channel structure of the plurality of channel structures has a cross-section of a plurality of ring shapes, wherein the channel layer, the channel-side dielectric layer, and the ferroelectric layer sequentially surround the insulating plug in the cross-section of the plurality of ring shapes,
wherein the ferroelectric layer contacts an upper surface of the semiconductor substrate at a lower surface of the channel structure, the channel-side dielectric layer completely covers an inner wall of the ferroelectric layer, the channel layer completely covers an inner wall of the channel-side dielectric layer, and the insulating plug is located in a column-shaped space defined by the channel layer and is surrounded by the channel layer.

3. The semiconductor device of claim 1, wherein the spacer extends along the sidewall of the plug barrier layer,
wherein an upper surface of the spacer is at a same vertical level as an upper surface of the plug barrier layer, and
wherein a lower surface of the spacer is at a higher vertical level than a lower surface of the plug barrier layer.

4. The semiconductor device of claim 1, wherein each conductive line structure of the plurality of conductive line structures comprises a buried conductive layer, a conductive barrier layer surrounding an outer surface of the buried conductive layer, a first gate insulating layer surrounding an outer surface of the conductive barrier layer, and a second gate insulating layer surrounding an outer surface of the first gate insulating layer.

5. The semiconductor device of claim 4, wherein the second gate insulating layer comprises at least one of hafnium oxide or aluminum oxide.

6. The semiconductor device of claim 4, wherein the spacer of a respective plug structure of the plurality of plug structures contacts an upper surface of the second gate insulating layer that corresponds to the respective plug structure of the plurality of plug structures, and
wherein the plug barrier layer and the contact plug of the respective plug structure of the plurality of plug structures extends at least partially into a respective conductive line structure of the plurality of conductive line structures that corresponds to the plug barrier layer and the contact plug.

7. The semiconductor device of claim 4, wherein each conductive line structure of the plurality of conductive line structures comprises a third gate insulating layer surrounding an outer surface of the second gate insulating layer.

8. The semiconductor device of claim 7, wherein the third gate insulating layer comprises at least one of SiON, SiN, or SiO₂.

9. The semiconductor device of claim 4, wherein each channel structure of the plurality of channel structures comprises a third gate insulating layer surrounding an outer wall of the ferroelectric layer,
wherein the third gate insulating layer has a first surface contacting the ferroelectric layer and a second surface opposite to the first surface of the third gate insulating layer,
wherein at least a first portion of the second surface of the third gate insulating layer contacts the plurality of insulating layers, and
wherein a second portion of the second surface of the third gate insulating layer contacts the second gate insulating layer.

10. The semiconductor device of claim 1, wherein a thickness of the ferroelectric layer in the horizontal direction is greater than a thickness of the channel layer in the horizontal direction.

11. A semiconductor device comprising:
a semiconductor substrate having a memory cell region and a connection region, the connection region being adjacent to the memory cell region;
a gate stack comprising a plurality of conductive line structures and a plurality of insulating layers, the plurality of conductive line structures and the plurality of insulating layers extending in a first direction and a second direction, the first direction and the second direction intersecting each other and parallel to a main surface of the semiconductor substrate, and the plurality of conductive line structures and the plurality of insulating layers being stacked alternately in a third direction perpendicular to the main surface of the semiconductor substrate;
a channel structure located in the memory cell region, the channel structure extending through the gate stack in the third direction; and
a plurality of plug structures arranged in a stepped configuration in the connection region, wherein a plurality of first ends of the plurality of plug structures are coplanar with each other, and a plurality of second ends of the plurality of plug structures are respectively connected to corresponding conductive line structures among the plurality of conductive line structures, the plurality of second ends being opposite to the plurality of first ends,
wherein the channel structure comprises a channel layer, a channel-side dielectric layer, and a ferroelectric layer sequentially surround a lower surface and a side surface of an insulating plug in a U shape,
wherein each conductive line structure of the plurality of conductive line structures comprises a buried conductive layer, a conductive barrier layer surrounding an outer surface of the buried conductive layer, a first gate insulating layer surrounding an outer surface of the conductive barrier layer, and a second gate insulating layer surrounding an outer surface of the first gate insulating layer, and
wherein a spacer on a sidewall of a respective plug structure of the plurality of plug structures contacts an upper surface of the second gate insulating layer that corresponds to the respective plug structure of the plurality of plug structures, and the second end of the respective plug structure of the plurality of plug structures extends to the buried conductive layer that corresponds to the respective plug structure of the plurality of plug structures.

12. The semiconductor device of claim 11, wherein the second gate insulating layer comprises at least one of hafnium oxide or aluminum oxide.

13. The semiconductor device of claim 11, comprising, in a bonding surface between the plurality of conductive line structures and the channel structure, a third gate insulating layer located between the ferroelectric layer and the second gate insulating layer.

14. The semiconductor device of claim 13, wherein the third gate insulating layer comprises at least one of SiON, SiN, or SiO₂.

15. The semiconductor device of claim 13, wherein the third gate insulating layer surrounds an upper surface and a lower surface of the plurality of conductive line structures.

16. The semiconductor device of claim 13, wherein the third gate insulating layer surrounds a sidewall of the ferroelectric layer.

17. The semiconductor device of claim 11, wherein the plug structure comprises a contact plug and a plug barrier layer,
wherein the plug barrier layer is between the contact plug and the spacer, and
wherein the plug barrier layer conformally surrounds a lower surface and a side surface of the contact plug.

18. The semiconductor device of claim 11, comprising:
an upper insulating layer above the channel structure;
a bit line extending in the second direction on the upper insulating layer; and
a bit line contact connected to the bit line, the bit line contact passing through the upper insulating layer,
wherein the channel structure is connected to the bit line via the bit line contact.

19. The semiconductor device of claim 11, wherein the first gate insulating layer comprises silicon oxide.

20. A semiconductor device comprising:
a semiconductor substrate having a memory cell region and a connection region, the connection region being adjacent to the memory cell region;
a gate stack comprising a plurality of conductive line structures and a plurality of insulating layers, the plurality of conductive line structures and the plurality of insulating layers extending in a first direction and a second direction, the first direction and the second direction intersecting each other and parallel to a main surface of the semiconductor substrate, and the plurality of conductive line structures and the plurality of insulating layers being stacked alternately in a third direction perpendicular to the main surface of the semiconductor substrate;
a channel structure located in the memory cell region, the channel structure extending through the gate stack in the third direction;
a bit line extending in the second direction, the bit line being at a higher vertical level than the channel structure, and the bit line being connected to the channel structure; and
a plurality of plug structures arranged in a stepped configuration in the connection region, wherein a plurality of first ends of the plurality of plug structures are coplanar with each other, and a plurality of second ends of the plurality of plug structures are respectively connected to corresponding conductive line structures among the plurality of conductive line structures, the plurality of second ends being opposite to the plurality of first ends,
wherein the channel structure comprises a channel layer, a channel-side dielectric layer, and a ferroelectric layer sequentially surround a lower surface and a side surface of an insulating plug in a 'U' shape,
wherein each conductive line structure of the plurality of conductive line structures comprises a buried conductive layer, a conductive barrier layer surrounding an outer surface of the buried conductive layer, a first gate insulating layer comprising silicon oxide and surrounding an outer surface of the conductive barrier layer, and a second gate insulating layer comprising a high-k material and surrounding an outer surface of the first gate insulating layer,
wherein each plug structure of the plurality of plug structures comprises a contact plug, a plug barrier layer surrounding a lower surface and a side surface of the contact plug, and a spacer partially surrounding a sidewall of the plug barrier layer, and
wherein the second end of a respective plug structure of the plurality of plug structures extends to the buried conductive layer that corresponds to the respective plug structure of the plurality of plug structures, and the spacer of the respective plug structure of the plurality of plug structures contacts an upper surface of the second gate insulating layer that corresponds to the respective plug structure of the plurality of plug structures.
